(19) United States
(12) Patent Application Publication
(10) Pub. No.: US 2009/0238994 A1
(43) Pub. Date: Sep. 24, 2009

(54) METHOD FOR PRODUCING A METAL CONTACT STRUCTURE OF A SOLAR CELL

(75) Inventors: Ansgar Mette, Leipzig (DE); Christian Schetter, Freiburg (DE); Stefan Glunz, Freiburg (DE); Philipp Richter, Hillsboro, OR (US)

Correspondence Address: VOLPE AND KOENIG, P.C., UNITED PLAZA, SUITE 1600, 30 SOUTH 17TH STREET, PHILADELPHIA, PA, 19103, US

(73) Assignee: Fraunhofer-Gesellschaft Zur Forderung Der Angewandten Forschung E.V., Munchen (DE)

(21) Appl. No.: 12/162,062

(22) PCT Filed: Jan. 25, 2007
(86) PCT No.: PCT/EP07/00630

§ 371 Date: Jul. 24, 2008

(30) Foreign Application Priority Data
Jan. 25, 2006 (DE) 10 2006 003 607.7
Jun. 30, 2006 (DE) 10 2006 030 822.0

(51) Int. Cl. H01L 31/0224; B05D 3/06; B05D 5/12

(52) U.S. Cl. 427/554; 427/74

(57) ABSTRACT

A method for producing a metal contact structure of a solar cell is provided and includes the following steps: applying a metal contact structure to a surface of the solar cell, reinforcing the metal contact structure in an electrolytic bath. The invention is characterized by the metal contact structure being applied by applying a metal-containing ink to the surface of the solar cell by at least one pressurized nozzle.

The invention relates to a method for producing a metal contact structure of a solar cell.

A solar cell represents a planar semi-conductor element, in which via incident electromagnetic radiation a separation of voltage carriers is created such that a potential develops between at least two contacts of the solar cell, and electric power can be tapped from the solar cell via an external electric circuit connected to the contacts.

The voltage carriers are here combined via metal contact structures such that by contacting these contact structures at one or more contact sites the voltage carriers can be fed to the external electric circuit.

For this purpose, typically grid-like metal contact structures are applied onto the surface of the solar cell, which cover the surface of the solar cell like fingers such that from all areas of the solar cell, the voltage carriers engage the contact structure and electricity can flow in the contact structure to the contact site and therefrom into the external circuit.

In order to avoid losses, the metal contact structure must be provided, on the one hand, with a low contact resistance to the contacting semiconductor area of the solar cell and, on the other hand, the resistivity of the contact structure must be low.

When the metal contact structure serves to contact the front of the solar cell, which also serves to illuminate the solar cell, the contact structure must still cover the front of the solar cell over an area as small as possible, in order to minimize the losses caused by shadows.

For producing such contact structures it is known to completely apply a silver-bearing paste over the entire contact grid in a single step by way of screen printing (silk screening). However, here large contact fingers develop with limited conductivity and high electric contact resistance towards the semiconductors.

Furthermore, it is known first to apply a grid-like metallic contact structure by way of screen printing onto the front of a silicon solar cell and subsequently to reinforce the contact structure in an electrolytic bath. In this galvanic (electricity-induced) reinforcement, the solar cell and a metal electrode are inserted in the electrolytic bath, with both the contact structure as well as the metal electrode being contacted so that a potential can be created between them such that metal ions originating in the metal electrode can move through the electrolytic bath and accumulate at the metal contact structure of the solar cell and thus reinforce it.

For the industrial production it is essential that the entire production process of the solar cell can be performed in a simple and low-cost manner, particularly the production of the contact structure, without considerably interfering with the effectiveness of the solar cell by the production method selected.

The present invention is therefore based on the object to provide a method for producing a contact structure of a solar cell, which can be executed in a cost-effective and quick fashion and on the other hand reduces to a minimum the above-mentioned potential losses.

This object is attained in a method for producing a metal contact structure of a solar cell according to claim 1. Advantageous embodiments of the method according to the invention are discernible from the sub-claims 2 through 17.

The method according to the invention differs from prior art in principle such that first the metal contact structure is created by a metalliferous ink, which via at least one pressurized nozzle is applied on the surface of the solar cell and subsequently the metal contact structure is reinforced in an electrolytic bath. The reinforcement can here occur in form of a known non-electric reinforcement using different chemical potentials or such that in an electrolytic bath a potential difference between a metal electrode and a metal contact structure is created electrically and thus a galvanic (electricity-induced) reinforcement occurs.

Contrary to the serigraphic methods, in which a sieve is placed onto the surface of the solar cell and a serigraphic paste is pressed via a doctor through the sieve onto the surface of the solar cell, in the method according to the invention the contact structure develops by applying the metalliferous ink using a pressurized nozzle, which is moved essentially parallel in reference to the surface of the solar cell.

In this way, no serigraphic sieve is necessary, because the contact structure develops from the relative motion of the surface of the solar cell in reference to the pressurized nozzle, thus costs can be saved:

The method according to the invention can be used for differently sized solar cells by adjusting the motion pattern of the pressurized nozzle to the size of the solar cell in reference to the surface of the solar cell.

Using the method according to the invention can additionally implement various forms of metal contact structures. In particular the production of all common contact structures, i.e. grid-like, comb-like, or stellar contact structures is possible.

In this way, various sizes and forms of contact structures can be created without requiring an appropriate, special serigraphic sieve to be created.

Another advantage of the method according to the invention comprises that, when the metalliferous ink is applied, the solar cell is impinged with only low pressure in reference to conventional serigraphic methods. This way, the risk of breakage reduces when producing the contact structure and furthermore, irregularities in the surface of the solar cell can be easily compensated: On the one hand, by the distance between the pressurized nozzle and the surface of the solar cell any irregularities in the surface of the solar cell are irrelevant. On the other hand, in case of considerably irregularities, the pressurized nozzle can easily be guided back to said irregularities so that an approximately constant distance is given to the surface.

Examinations by the applicant have shown that for typical silicon solar cells a minimum distance of the pressurized nozzle to the surface of the solar cell amounting to at least 100 μm is particularly suitable for the application of the method according to the invention in typical silicon solar cells.

In a typical embodiment the metalliferous ink is applied on the solar cell via an inkjet printing method. The inkjet printing method for printing materials with inks is known and particularly widely used in inkjet printers. An overview of the technology of inkjet printing methods is found in J. Heinzl, C. H. Hertz, “Ink-Jet Printing”, Advances in Electronics and Electron Physics, Vol. 65 (1985), pp. 91-112.

In this embodiment of the method according to the invention it is essential that an already developed inkjet-printing method is being applied and is combined with the reinforcement of the contract structures in an electrolytic bath, so that on the one hand the cost-effective and inkjet technology flexible with regard to the design of the metallic contact structure can be used and on the other hand the advantages of a reinforcement in an electrolytic bath can be used.

Furthermore, disadvantages are avoided which occur in a production of the contact structure exclusively using inkjet printing. The primary disadvantage to be mentioned here is the fact that due to the relatively small amount of metal applied per inkjet run several processing steps are necessary to create a contact structure of sufficient strength and/or conductivity.

Furthermore, in a pure inkjet process only a smaller ratio of linear height to linear width can be achieved for the finger-like structures of the contact structures, while the combination of inkjet printing and a subsequent reinforcement in an electrolytic bath allows to create lower linear widths with identical conductive resistance, so that there is less shadowing of the solar cell under illumination and thus a higher effectiveness of the solar cell can be achieved.

In another advantageous embodiment of the method according to the invention the metal contact structure is applied on the solar cell via an aerosol-printing method. In this method the metalliferous ink is also applied on the surface of the solar cell via at least one pressurized nozzle.

In contrast to the inkjet printing method, in the aerosol method first an aerosol of the printing ink is produced. This aerosol is guided to the solar cell via a pressurized nozzle, with the pressurized nozzle being mounted to a print head, in which the aerosol is bundled via a focusing gas and is guided to the pressurized nozzle in a focused form.

In this way, the pressurized nozzle is prevented from contacting the ink so that the risk of the pressurized nozzle becoming clogged is considerably reduced in reference to the inkjet printing method.

Furthermore, the focusing via the focusing gas allows finer lines to be printed in reference to the inkjet printing method, so that after the reinforcement in the electrolytic bath even finer contact structures and a greater aspect ratio is possible and thus loss by shadowing can be avoided.

Experiments of the applicant have shown that by focusing the aerosol via the focusing gas a greater distance between the pressurized nozzle and the surface of the solar cell is possible than in the inkjet printing method without any smearing of the printing ink developing. In particular, in the aerosol method a distance of 1 mm may be given between the pressurized nozzle and the surface of the solar cell so that even major irregularities of the surface of the solar cell require no secondary processing by the pressurized nozzle.

Due to the fact that in the method according to the invention the application of the metallic structures and the reinforcement via the electrolytic bath occurs in two steps it is possible to use one metal for each step. This way, a first metal may be included in the metalliferous ink and thus form the metallic contact structure on the surface of the solar cell. A second metal can be selected for the reinforcement in the electrolytic bath, for example for the metallic electrode in the galvanic reinforcement, so that the reinforcement occurs via this second metal.

In another advantageous embodiment, different metals are used for applying the metallic contact structure and for reinforcement in the electrolytic bath. This is advantageous in that the selection of the metal can be optimized for various functions:

For example, it is advantageous that the metal of the metalliferous ink applied in the first step as the metallic contact structure is selected such that a low electric contact resistance and strong mechanic adhesion to the surface of the solar cell develop.

During reinforcement in the electrolytic bath, however, it is advantageous to select a metal which has a low specific conductive resistance so that the conductive resistance in the contact structure is minimized.

At the side the metallic contact structure is to be applied to, typical silicon solar cells show a n-doped area. Here, advantageously the specific contact resistance between the contact structure and the n-doped area shall amount to less than 1×10⁻³ Ωcm².

Therefore, nickel is particularly suitable as the metallic component of the ink, because nickel can result in low specific contact resistances. Nickel further shows good adhesion to the silicon surface so that a later separation of the contact structure can be avoided.

For the electrolytic reinforcement the use of metal is advantageous having a specific resistivity<3×10⁻⁸ Ωm, in order to avoid joule losses caused by the resistivity of the contact grid. Particularly the use of silver or copper is advantageous because these metals have a low specific resistivity.

In general all known metalliferous inks can be used for the method according to the invention. Experiments of the applicant have shown, however, that certain metalliferous inks have particular advantages.

For the method according to the invention, advantageously a silver-containing screen printing paste, known per se, can be used as the metallic ink, which is diluted with solvents such that it has approximately 60% by weight silver particles with a size ranging from 1 μm to 5 μm. The use of such a diluted screen printing paste is advantageous in that such pastes are widely used in screen printing processes, and thus have been thoroughly researched and are commercially available, and by the additional dilution the risk for clogging the pressurized nozzle is reduced.

Experiments of the applicant have shown that the use of the screen printing paste for the inkjet printing method based on the particle size of the metal particles in the screen printing paste frequently leads to the pressurized nozzle clogging such that it is advantageous to apply the screen printing past via aerosol print, because here no contact of the paste with the pressurized nozzle occurs and thus the probability of clogging is considerably reduced.

Additionally, the use of a metalliferous ink having nano-particles is advantageous with the size of the metal particles provided as nano-particles ranging from 20 nm to 1000 nm. The weight ratio of the metal particles in reference to the paste usefully ranges from 10% by weight to 20% by weight.

Experiments of the applicants have shown that such an ink based on the small particle size particularly in connection with the aerosol printing method allows the printing of very fine lines having a width of less than 10 μm.

Furthermore, this printing ink is also suitable for the application of the inkjet printing method, because based on the small particle size there is less risk for the pressurized nozzle to get clogged.

Furthermore, it is advantageous to use a metalliferous ink for the method according to the invention, in which the metal is provided in a dissolved form, i.e. in an ionic form. Such inks are also called metal-organic inks. The metal portion of these inks amounts to approx. 20% by weight.

Experiments by the applicant have shown that the use of this ink is particularly suitable for inkjet printing because the metal is not provided as particles in the printing ink and thus any clogging of the pressurized nozzle is almost excluded. Furthermore, the printing in very fine lines is possible due to the presence of the metal in an ionic form (and not in form of metal particles).

The surface of a solar cell to be applied on a metallic contacting structure is usually provided in a dielectric layer, which developed based on the surface by oxidation or which has been applied intentionally, in order to improve the reflective characteristics of the surface and thus to absorb an increased portion of the light impinging the solar cells in the solar cell.

The contact structure must contact through the dielectric layer the area of the solar cell located below for a functioning contacting.

For this purpose, it is known from the screen printing methods to add glass frit to the screen printing paste and after the contact structure has been printed to create kilning of the metal structure by way of a temperature step (heating the solar cell) through the dielectric layer, supported by the glass frit.

The use of glass frit is disadvantageous, though, because the etching process of the glass frit through the dielectric layer can only be controlled approximately by selecting the temperature and the duration of the temperature step so that the areas of the solar cell located underneath the dielectric layer may be damaged, particularly the n-doped area.

Therefore, in an advantageous embodiment of the method according to the invention, the dielectric layer on the surface of the solar cell to which the contact structures is to be applied is removed via a laser prior to the application of the metalliferous ink. Here, the dielectric layer is only removed in the areas in which a contact shall occur between the metallic contact structure and the solar cell.

In order to prevent any oxidation or contamination of the surface of the solar cell in these areas after the removal of the dielectric layer it is advantageous to remove the dielectric layer via the laser immediately prior to applying the metalliferous ink on the surface of the solar cell.

Here, it is particularly advantageous when the laser or at least the outlet opening of the laser is connected in a fixed manner to the pressurized nozzle, such as for example a flexible light conductor. This way lasers and pressurized nozzles can be adjusted such that in a relative motion of the solar cell and the pressurized nozzle first via the laser the dielectric layer is removed and immediately thereafter the application of the metalliferous contact structure occurs via the pressurized nozzle. This way, no adjustment between the processing steps of removing the dielectric layer and the application of the metallic contact structure is necessary, rather the dielectric layer is removed in the same processing step in which the metalliferous ink is applied as well.

In the method according to the invention first a metallic contact structure is applied, which then is reinforced in an electrolytic bath. In order to improve the contact of the metallic contract structure and the reinforcement it is advantageous if prior and/or after the reinforcement in the electrolytic bath the solar cell is heated to a temperature ranging from 100° C. and 900° C. for a term lasting from one second to thirty minutes.

Heating the solar cell prior to reinforcement in an electrolytic bath is advantageous in that solvents included in the ink evaporate prior to the solar cell being immersed in the electrolytic bath. The step of the temperature treatment and thus the sintering can also be executed with a laser beam following directly after the application of the metal layer.

Typically the method according to the invention is used in order to apply a metallic contact structure to the front of the solar cell. The rear of the solar cell is typically provided with a full-surface metallization, which represents the rear contact of the solar cell.

The features of the solar cell to create a separation of charge carriers when radiated with light can therefore be used to perform a galvanic (electricity-reducing) reinforcement without the solar cell having to be contacted in the galvanic bath.

For this purpose, advantageously the solar cells are inserted into the galvanic bath and radiated with light so that a potential difference is created between the front and the back of the solar cell. The potential of the metal electrode can only be selected such that a potential difference develops between the metal electrode and the front of the solar cell and thus the metal contact structure applied via the printing process such that a reinforcement of the metallic structure occurs in the electrolytic bath.

In another advantageous embodiment of the method according to the invention the rear of the solar cell is contacted during the galvanized reinforcement. As above described, the solar cell is illuminated during the galvanic reinforcement such that there is a potential difference between the front and the rear contacts. A potential difference is selected between the contacted rear of the solar cell and the metal electrode in the electrolytic bath such that no dissolution of the rear metallization of the solar cell occurs in the electrolytic bath. In this way, it is achieved that the galvanized reinforcement only relates to the front contact of the solar cell and thus only the metal electrode in the electrolytic bath dissolves, but not the rear contact of the solar cell.

An exemplary embodiment of the method according to the invention is explained in greater detail using the figures. Shown are:

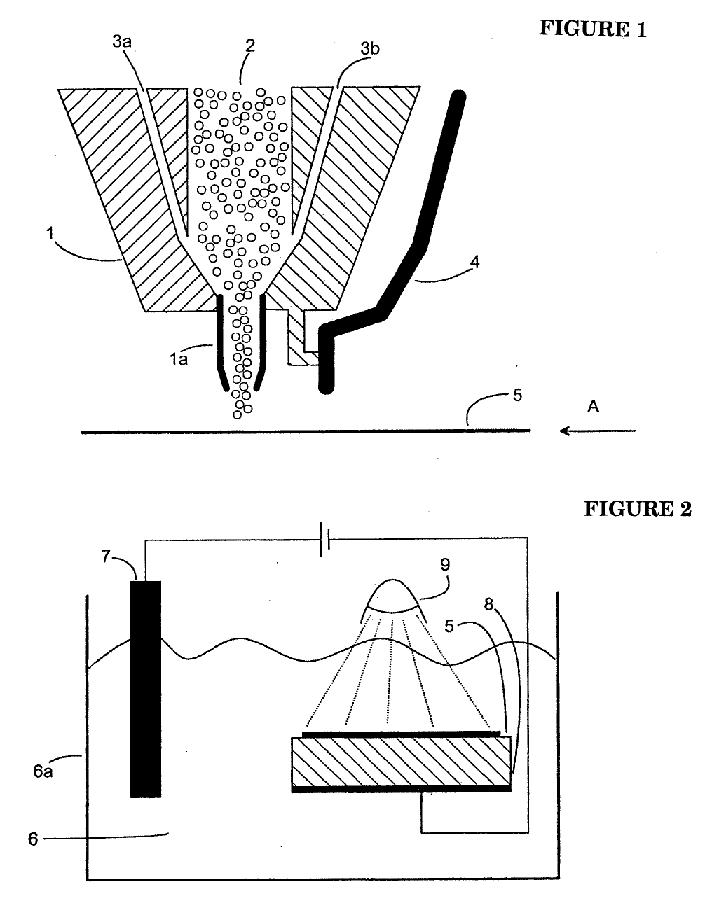

FIG. 1 illustrates the processing step of the method according to the invention by the dielectric layer of the solar cell being opened by a laser and a metalliferous printing ink being applied to the surface of the solar cell via aerosol spray, and

FIG. 2 illustrates the subsequent processing step of the method according to the invention in which the contact structure is galvanically reinforced at the front of the solar cell.

FIG. 1 shows a printing head 1 with a pressurized nozzle 1a, which serves to apply an aerosol 2 on the surface 5 of a solar cell. The printing head 1 has inlets 3a and 3b in which focusing gas is introduced so that the aerosol 2 is focused by a circular current of the focusing gases such that it exits the pressurized nozzle 1a without contacting said pressurized nozzle.

Further, a light conductor 4 is mounted at the printing head, which is connected to a laser (not shown). Via the light conductor 4, the surface 5 of the solar cell is radiated with laser light so that the dielectric layer on the surface of the solar cell is removed in the radiated areas by way of vaporization. The pressurized nozzle 1a and the light conductor 4 are here adjusted such that during a motion of the solar cell according to direction A the aerosol is applied in the area of the dielectric layer opened by the laser radiation on the surface 5 of the solar cell.

The aerosol 2 is created from a screen printing paste which comprises approximately 60% by weight nickel particles having a diameter from 1 to 5 μm. Due to the fact that the dielectric layer of the solar cell is opened by the laser the screen printing paste, from which the aerosol 2 is yielded, contains no glass frit, because an etching through the dielectric layer is unnecessary. The remaining weight portions of screen printing paste, missing up to 100% by weight, comprises binders and solvents.

The printing process occurs under normal atmospheric conditions at room temperature.

The relative motion between the surface 5 of the solar cell and the printing head 1 with the pressurized nozzle 1a and the light conductor 4 is achieved by the solar cell being supported on an XY-table, which can displace it perpendicular in the direction of the spray direction of the pressurized nozzle (i.e. in FIG. 1 towards the right and the left and into the image level and out of it). Subsequently the temperature step occurs at approx. 400° C. in order to perform the contact formation of the applied metal paste to the semiconductor.

After the conclusion of this processing step, a metallic contact structure results having a narrow linear width is applied to the surface 5 via the aerosol. For the screen printing paste nickel was used as the metal for the metal particles so that the contact structure applied via the aerosol has one the one hand a low contact resistance with the n-doping of the silicon solar cell located at the surface at the solar cell and furthermore a good adhesion is provided between the contact structure and the surface 5 of the solar cell.

After this processing step has been concluded the solar cell is placed into an electrolytic bath for a galvanized reinforcement, as shown in FIG. 2.

An electrolytic bath 6 is located in a container 6a, into which a silver electrode 7 and the solar cell 8 are inserted, with its surface 5 being provided with a metallic contact structure applied in advance. The rear contact of the solar cell located at the bottom in the drawing is connected to the negative contact of a voltage source, with its positive contact being connected to the silver electrode 7. A light source 9 impinges the front of the solar cell 8 with light such that a potential develops between the front contact, located at the top in the drawing with the contact structure applied via aerosol spray, and the rear contact. The potential ratio between the silver electrode 7, front contact, and rear contact of the solar cell 8 is now selected such that silver ions originating from the silver electrode 7 accumulate at the contact structure at the front 5 of the solar cell 8 by the electrolytic bath 6 such that it is galvanically reinforced.

Further, the potential at the rear of the solar cell 8 is selected such that no metal ions can transfer from the rear of the solar cell to the electrolytic bath so that the rear contact of the solar cell 8 does not dissolve. The potential of the front of the solar cell is here lower than the potential at the rear of the solar cell and that one in turn is lower than the potential of the electrode.

1. A method for producing a metallic contact structure of a solar cell (8) comprising the processing steps:
applying a metallic contact structure on a surface (5) of a solar cell (8), by applying a metalliferous ink (2) on the surface (5) of the solar cell (8) using at least one pressurized nozzle (1a), and
reinforcing the metallic contact structure using an electrolytic bath (6).

2. A method for producing a contact structures of a solar cell (8) according to claim 1, wherein the pressurized nozzle (1a) does not contact the surface (5) of the solar cell (8) when applying the metalliferous ink, with a distance of the pressurized nozzle (1a) from the surface (5) of the solar cell (8) amounts to at least 100 μm when the metalliferous ink is applied.

3. A method for producing a contact structure of a solar cell (8) according to claim 1, wherein the metallic contact structure is applied to the solar cell (8) via an inkjet printing method.

4. A method to produce a contact structure of a solar cell (8) according to claim 1, wherein the metallic contract structure is applied to the solar cell (8) via an aerosol printing process.

5. A method for producing a contact structure of a solar cell (8) according to claim 1, wherein the metalliferous ink comprises a first metal and that a second metal is used for galvanic reinforcement, with the first metal and the second metal being different.

6. A method for producing a contact structure of a solar cell (8) according to claim 5, wherein the first metal has a specific resistivity to a n-doped silicon layer at the surface of the solar cell that is smaller than 1×10⁻³ Ωcm².

7. A method for producing a contact structure of a solar cell (8) according to claim 1, wherein the second metal has a specific resistivity<3×10⁻⁸ Ωm.

8. A method for producing a contact structure of a solar cell (8) according to claim 1, wherein the metalliferous ink is a silver-screen printing paste, which is provided with approximately 60% by weight silver particles having a size ranging from 1 μm to 5 μm.

9. A method for producing a contact structure of a solar cell (8) according to claim 8, wherein the silver-screen printing paste is applied via aerosol spray.

10. A method for producing a contact structure of a solar cell (8) according to claim 1, wherein the metalliferous ink is a paste containing nano-particles, comprising metallic particles with a size ranging from 20 nm to 1000 nm, with a weight portion of the metal particles in the paste ranging from 10% by weight to 30% by weight.

11. A method for producing a contact structure of a solar cell (8) according to claim 1, wherein the metalliferous ink is a metal-organic ink, in which the metal is provided in a dissolved form.

12. A method for producing a contact structure of a solar cell (8) according to claim 10, wherein the metalliferous ink is applied via inkjet printing.

13. A method for producing a contact structure of a solar cell (8) according to claim 1, further comprising prior to applying the metallic contact structure, at least partially removing a dielectric layer on the surface (5) of the solar cell (8) in areas in which the metallic contact structure is applied to the surface (5) of the solar cell (8).

14. A method for producing a contact structure of a solar cell (8) according to claim 13, wherein the dielectric layer on the surface (5) of the solar cell (8) is removed via a laser.

15. A method for producing a contact structure of a solar cell (8) according to claim 1, further comprising at least one of prior to or after the reinforcement in the electrolytic bath of the metallic contact structure, heating the solar cell to a temperature ranging from 100° C. to 900° C. for a term lasting from 1 sec. and 30 minutes.

16. A method for producing a contact structure of a solar cell (8) according to claim 1, wherein the metallic contact structure is applied to a front (5) of the solar cell (8), the reinforcement is a galvanic (electricity induced) reinforcement, and in the galvanic reinforcement a potential difference is created between the front and a rear of the solar cell (8) by radiating the solar cell (8) with light.

17. A method for producing a contact structure of a solar cell (8) according to claim 16, further comprising contacting the rear of the solar cell (8) electrically in order to create a potential difference to a metal electrode (7) located in the electrolytic bath and the potential difference between the rear of the solar cell (8) and the metal electrode (7) is selected such that no dissolution of a metallization of the rear of the solar cell (8) occurs in the electrolytic bath.
